(19) United States
(12) Patent Application Publication
(10) Pub. No.: US 2002/0047122 A1
(43) Pub. Date: Apr. 25, 2002

(54) Polycrystalline silicon layer, its growth method and semiconductor device

(76) Inventors: Hisayoshi Yamoto, Kanagawa (JP); Hideo Yamanaka, Kanagawa (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 09/733,473

(22) Filed: Dec. 8, 2000

(30) Foreign Application Priority Data
Dec. 10, 1999 (JP) P11-352350

(51) Int. Cl. H01L 29/04; H01L 31/036; H01L 31/112; H01L 21/84

(52) U.S. Cl. 257/66; 438/149; 257/64; 438/150; 438/166; 257/65

(57) ABSTRACT

In case of growing a polycrystalline silicon layer (10) by catalytic CVD on a substrate (4) such as glass substrate, quartz substrate or silicon substrate having formed an oxide film on its surface, the total pressure of the growth atmosphere is maintained in the range from 1.33×10⁻³ Pa to 4 Pa at least in the initial period of the growth, or alternatively, partial pressure of oxygen and moisture in the grow that atmosphere is maintained in the range from 6.65×10⁻¹⁰ to 2×10⁻⁶ Pa at least in the initial period of the growth. Thus, the maximum oxygen concentration of the grown polycrystalline silicon layer (10) becomes not higher than 3×10¹⁸ atoms/cm⁻³ at least in a region of the polycrystalline silicon layer with the thickness of 10 nm from the boundary with the substrate (4). It is thus ensured to grow a high-quality polycrystalline silicon layer having a quality required for use as a TFT polycrystalline silicon layer by catalytic CVD.

### BACKGROUND OF THE INVENTION

1. Field of the Invention

This invention relates to a polycrystalline silicon layer, its growth method and semiconductor device, which are suitable for application to a thin-film transistor (TFT), for example.

2. Description of the Related Arts

For fabricating a polycrystalline silicon (Si) layer, typically used heretofore were a method using atmospheric pressure chemical vapor deposition (APCVD) to decompose silane (SiH₄) or disilane (Si₂H₆) under a temperature around 600 to 600° C. in hydrogen atmosphere and under the pressure of 1×10⁵ Pa (760 Torr) and grow the layer, a method using low-pressure chemical vapor deposition (LPCVD) to decompose and grow silane (SiH₄) or disilane (Si₂H₆) under a temperature around 600 to 600° C. in hydrogen atmosphere and under the pressure of (0.53˜1.33)×10² Pa (0.4˜1 Torr) and grow the layer, or a method using plasma CVD to decompose silane (SiH₄) or disilane (Si₂H₆) under a temperature around 200 to 400° C. in hydrogen atmosphere and under the pressure of (0.26˜2.6)×10² Pa (0.2˜2 Torr),thereby grow an amorphous silicon layer and thereafter annealing the amorphous silicon layer under a high temperature around 800 to 1300° C. so as to grow crystal grains.

However, those methods for growing polycrystalline silicon layers by APCVD and LPCVD involve the problem that their growth temperatures are high. In APCVD and LPCVD, since all of the energy required for chemical interaction and growth during growth of polycrystalline silicon layers is supplied in form of heat energy by heating, the growth temperature cannot be largely decreased from about 600° C. Additionally, since interaction efficiency of reactant gas like silane is generally as low as several % or less, almost all of such reactant gas is discharged and discarded, cost of reactant gas becomes high and cost required for the discard is also high. On the other hand, the method for fabricating a polycrystalline silicon layer by crystallizing an amorphous silicon layer involves the problem that it needs an annealing apparatus for high-temperature annealing.

Recently, as a growth method of polycrystalline silicon layers overcoming those problems, a growth method called catalytic CVD are being remarked (for example, Japanese Patent Laid-Open Publication No. hei 10-83988 and Applied Physics, Vol. 66, No. 10, p. 1094(1997)). This catalytic CVD uses catalytic cracking reaction between a heated catalyst and reactant gas (source material gas). Catalytic CVD, in its first stage, brings reactant gas (such as silane and hydrogen in case of using silane as the source material of silicon) into contact with a hot catalyst heated to 1600 through 1800° C. for example, to activate the reactant gas and thereby make silicon atoms, or clusters of silicon atoms, and hydrogen atoms, or clusters of hydrogen atoms, having high energies, and in its second stage, raises the temperature of these silicon atoms and hydrogen atoms or molecules having high energies, or a substrate that supplies their clusters, to a high temperature, thereby to supply and support the energy required particularly for silicon atoms to form single-crystal grains. Therefore, catalytic CVD enables growth of a polycrystalline silicon layer even at a lower temperature than those of conventional APCVD and LPCVD, such as around 350° C. for example.

However, according to results of various experiments made by the Inventor, in the case where a polycrystalline silicon layer is grown at a low temperature by existing catalytic CVD, oxygen is more liable to be brought into the growth layer than that those grown by conventional APCVD and LPCVD, and the oxygen concentration in the polycrystalline silicon layer obtained often exceeds several atomic % (at %). This amounts at least to 5×10²⁰ atoms/cm³ (atoms/cc) when converted into atomic concentration. Since the maximum solution of oxygen in silicon is 2.5×10¹⁸ atoms/cc (for example, Semiconductor Handbook 2nd Edition, pp. 128-129, edited by Hisayoshi Yanai, Ohmusha, 1977), and the oxygen concentration is far beyond the maximum solution of oxygen insilicon, 2.5×10¹⁸ atoms/cc. When oxygen over the maximum solution is contained in silicon, oxygen precipitates forming silicon oxide, and sometimes results in forming an oxide thin film around silicon crystal grains or sometimes results in forming oxide grains with a further increase of oxygen. It is already known that such a high oxygen concentration invites a rapid increase of resistance of a polycrystalline silicon layer (for example, Japanese Patent Publication No. 55-13426).

With these problems involved, polycrystalline silicon layers grown by existing catalytic CVD do not satisfy the requirement in quality necessary for polycrystalline silicon layers of TFT, for example.

That is, requirements in quality of polycrystalline silicon layer for TFT are:

(1) having a smooth surface;

(2) not exfoliating from the base;

(3) having a large grain size and a high crystallizing ratio;

(4) containing less impurity.

According to evaluation from these standpoints, polycrystalline silicon layers grown by existing catalytic CVD are in sufficient in quality.

### OBJECT AND SUMMARY OF THE INVENTION

It is therefore an object of the invention to provide a polycrystalline silicon layer growth method capable of growing a high-quality polycrystalline silicon layer satisfying the quality requirement for use as a TFT polycrystalline silicon layer, and a polycrystalline silicon layer made by the method and a semiconductor device using the polycrystalline silicon layer.

Toward solution of the above-mentioned problems involved in existing technologies, the Inventor made wide and detailed experiments and vigorous researches. They are outlined below.

That is, repeated were experiments of growing polycrystalline silicon layers by using catalytic CVD and variously changing process conditions under a low temperature range (200 through 600° C.) and then evaluating them. As a result, it was found that, for growing high-quality polycrystalline silicon layers by catalytic CVD, conditions such as pressure of the vapor-phase growth atmosphere, partial pressure of oxygen and moisture in the growth atmosphere, and so on, were absolutely different from those of conventional CVD. More specifically, when the growth pressure was 13.3 Pa (100 mTorr), for example, it was not possible to obtain desired polycrystalline layers having smooth surfaces, not exfoiliating and containing less impurity. Especially, polycrystalline silicon layers grown under 13.3 Pa (100 mTorr) exhibit high crystallizing ratios according to evaluation by Raman scattering, but results of measurement by secondary ion mass spectrometry show that polycrystalline silicon layers contain oxygen as much as 10 at % and cannot be used for TFT. On the other hand, by setting the total pressure of the growth atmosphere to a much lower pressure than that of existing catalytic CVD, e.g., in the range from 1.33×10⁻³ Pa to 4 Pa (from 0.01 mTorr to 30 mTorr), at least in the initial period of growth, it was confirmed that the maximum oxygen concentration at least near the boundary with the substrate was as very low as 5×10¹⁸ atoms/cc (0.001 at %), and high-quality polycrystalline silicon layers could be grown. Also when the partial pressure of oxygen and moisture in the growth atmosphere at least in the initial period of growth was set in the range from 6.65×10⁻¹⁰ Pa to 2×10⁻⁶ (from 0.005×10⁻⁶ mTorr to 15×10⁻⁶ mTorr), it was confirmed that the oxygen concentration at least near the boundary with the substrate was similarly as very low as 5×10¹⁸ atoms/cc (0.006 at %), and high-quality polycrystalline silicon layers could be grown. This partial pressure of oxygen and moisture can be obtained when oxygen and moisture around 0.5 ppm in total are contained in the reactant gas.

The present invention has been made through studies based on the above knowledge of the Inventor.

According to the first aspect of the invention, there is provided a polycrystalline silicon layer grown on a substrate by catalytic CVD, characterized in:

the maximum oxygen concentration thereof being not higher than 5×10¹⁸ atoms/cm³ at least in a region having the thickness of 10 nm from the boundary between the substrate and the single crystal silicon layer.

In the first aspect of the invention, the maximum oxygen concentration at least in a region with the thickness of 10 nm from the boundary between the substrate and the polycrystalline silicon layer is preferably not higher than 2.5×10¹⁸ atoms/cm³. Further, the maximum oxygen concentration at least in a region with the thickness of 50 nm, or 100 nm, from the boundary between the substrate and the polycrystalline silicon layer is preferably not higher than 2.5 10¹⁸ atoms/cm^{3.}

According to the second aspect of the invention, there is provided a polycrystalline silicon layer having a thickness not exceeding 100 nm grown by catalytic CVD on a substrate, characterized in:

the maximum oxygen concentration thereof being 5×10¹⁸ atoms/cm^{3.}

In the second aspect of the invention, thickness of the polycrystalline silicon layer may be not larger than 50 nm. Additionally, the maximum oxygen concentration is preferably not higher than 2.5×18¹⁸ atoms/cm³.

In the first and second aspect of the invention, the polycrystalline silicon layer is typically grown directly by catalytic CVD, but it may be one of those grown by other methods. For example, it may be one made by first growing an amorphous silicon layer and then crystallizing it by excimer laser annealing, for example.

According to the third aspect of the invention, there is provided a polycrystalline silicon layer grown on a substrate by catalytic CVD, characterized in:

being grown by maintaining the total pressure of the growth atmosphere in the range from 1.33×10⁻³ Pa to 4 Pa at least in an initial period of the growth.

According to the fourth aspect of the invention, there is provided a polycrystalline silicon layer grown on a substrate by catalytic CVD, characterized in:

being grown by maintaining the partial pressure of oxygen and moisture in the growth atmosphere in the range from 6.65×10⁻¹⁰ Pa to 2×10⁻⁶ Pa at least in an initial period of the growth.

According to the fifth aspect of the invention, there is provided a growth method for growing a polycrystalline silicon layer by catalytic CVD on a substrate, characterized in:

the total pressure of the growth atmosphere being maintained in the range from 1.33×10⁻³ Pa to 4 Pa at least in an initial period of the growth.

According to the sixth aspect of the invention, there is provided a growth method for growing a polycrystalline silicon layer by catalytic CVD on a substrate, characterized in:

the partial pressure of oxygen and moisture in the growth atmosphere being maintained in the range from 6.65×10⁻¹⁰ Pa to 2×10⁻⁶ Pa at least in an initial period of the growth.

According to the seventh aspect of the invention, there is provided a semiconductor device having a polycrystalline silicon layer which is grown by catalytic CVD on a substrate, characterized in:

the single polycrystalline layer having the maximum oxygen concentration of 5×10¹⁸ atoms/cm³ at least in a region thereof to be used as a carrier channel.

In the seventh aspect of the invention, the maximum oxygen concentration of the polycrystalline silicon layer is preferably 2.5×10¹⁸ atoms/cm³.

The semiconductor device maybe basically any that uses the polycrystalline silicon layer. Specifically, it may be a thin-film transistor (TFT), which is MISFET, or junction FET, bipolar transistor, or the like, for example. Thickness of the carrier channel region in TFT is typically around 10 through 100 nm.

In the present invention, growth temperature of the polycrystalline silicon film by catalytic CVD is, for example, 200 through 600° C.

According to the first aspect of the invention having the above-summarized structure, since the maximum oxygen concentration is not higher than 5×10¹⁸ atoms/cm³, which is much lower than that of a polycrystalline silicon layer grown at a low temperature by existing catalytic CVD at least in a region with the thickness of 10 nm from the boundary between the substrate and the polycrystalline silicon layer, a high-quality poly crystalline silicon layer excellent in surface morphology, crystal grain size, oxygen concentration, exfoliation property and crystallizing ratio can be obtained.

According to the second aspect of the invention having the above-summarized structure, since the maximum oxygen concentration is not higher than 5×10¹⁸ atoms/cm³, which is much lower than that of a polycrystalline silicon layer grown at a low temperature by existing catalytic CVD, a high-quality polycrystalline silicon layer excellent in surface morphology, crystal grain size, oxygen concentration, exfoliation property and crystallizing ratio can be obtained.

According to the third and fifth aspects of the invention having the above-summarized structures, since the total pressure of the growth atmosphere is set in the range from 1.33×10⁻³ Pa to 4 Pa at least in the initial period of growth, partial pressure of oxygen and moisture in the growth atmosphere can be maintained in the range from 6.65×10⁻³ Pa to 2×10⁻⁶ Pa at least in the initial period of growth, and the amount of oxygen brought into the growth layer can be diminished significantly. As a result, the maximum oxygen concentration is not higher than 5×10¹⁸ atoms/cm³, which is much lower than that of apolycrystalline silicon layer grown at a low temperature by existing catalytic CVD at least in a region with the thickness of 10nm from the boundary between the substrate and the polycrystalline silicon layer, and therefore, a high-quality polycrystalline silicon layer excellent in surface morphology, crystal grain size, oxygen concentration, exfoliation property and crystallizing ratio can be obtained.

According to the fourth and sixth aspects of the invention having the above-summarized structures, since the partial pressure of oxygen and moisture in the growth atmosphere is set in the range from 6.65×10⁻¹⁰ Pa to 2×10^{31 6} Pa at least in the initial period of growth, the amount of oxygen brought into the growth layer can be diminished significantly. As a result, the maximum oxygen concentration is not higher than 5×10¹⁸ atoms/cm³, which is much lower than that of a polycrystalline silicon layer grown at a low temperature by existing catalytic CVD at least in a region with the thickness of 10 nm from the boundary between the substrate and the polycrystalline silicon layer, and therefore, a high-quality polycrystalline silicon layer excellent in surface morphology, crystal grain size, oxygen concentration, exfoliation property and crystallizing ratio can be obtained.

According to the seventh aspect of the invention having the above-summarized structure, since the maximum oxygen concentration is not higher than 5×10¹⁸ atoms/cm³, which is much lower than that of a polycrystalline silicon layer grown at a low temperature by existing catalytic CVD at least in a region to be used as the carrier channel, the polycrystalline silicon layer has a high quality excellent in surface morphology, crystal grain size, oxygen concentration, exfoliation property and crystallizing ratio, and it is possible to obtain a high-performance semiconductor devicelike TFT having a high carrier mobility, by using this polycrystalline silicon layer.

The above, and other, objects, features and advantage of the present invention will become readily apparent from the following detailed description thereof which is to be read in connection with the accompanying drawings.

### BRIEF DESCRIPTION OF THE DRAWINGS

FIG. 1 is a schematic diagram that shows a catalytic CVD apparatus used in an embodiment of the invention;

FIGS. 2A and 2B are cross-sectional views for explaining a growth method of a polycrystalline silicon layer by catalytic CVD according to the first embodiment of the invention;

FIG. 3 is a schematic diagram that shows a result of SIMS measurement;

FIG. 4 is a schematic diagram that shows a result of SIMS measurement;

FIG. 5 is a schematic diagram that shows a result of SIMS measurement;

FIG. 6 is a schematic diagram that shows a result of SIMS measurement;

FIG. 7 is a schematic diagram that shows a result of SIMS measurement;

FIG. 8 is a schematic diagram that shows a result of SIMS measurement;

FIG. 9 is a schematic diagram that shows a result of SIMS measurement;

FIG. 10 is a sectional transmission electron microscopic photograph of a sample;

FIG. 11 is a sectional transmission electron microscopic photograph of a sample;

FIG. 12 is a sectional transmission electron microscopic photograph of a sample;

FIG. 13 is a sectional transmission electron microscopic photograph of a sample;

FIG. 14 is a sectional transmission electron microscopic photograph of a sample;

FIG. 15 is a sectional transmission electron microscopic photograph of a sample;

FIG. 16 is a sectional transmission electron microscopic photograph of a sample;

FIG. 17 is a sectional transmission electron microscopic photograph of a sample;

FIG. 18 is a sectional transmission electron microscopic photograph of a sample;

FIG. 19 is a sectional transmission electron microscopic photograph of a sample;

FIG. 20 is a sectional transmission electron microscopic photograph of a sample;

FIG. 21 is a sectional transmission electron microscopic photograph of a sample;

FIG. 22 is a sectional transmission electron microscopic photograph of a sample;

FIG. 23 is a sectional transmission electron microscopic photograph of a sample;

FIG. 24 is a sectional transmission electron microscopic photograph of a sample; and

FIG. 25 is a cross-sectional view that shows TFT using a polycrystalline silicon layer grown by catalytic CVD according to an embodiment of the invention.

### DETAILED DESCRIPTION OF THE PREFERRED EMBODIMENTS

An embodiment of the invention is explained below with reference to the drawings.

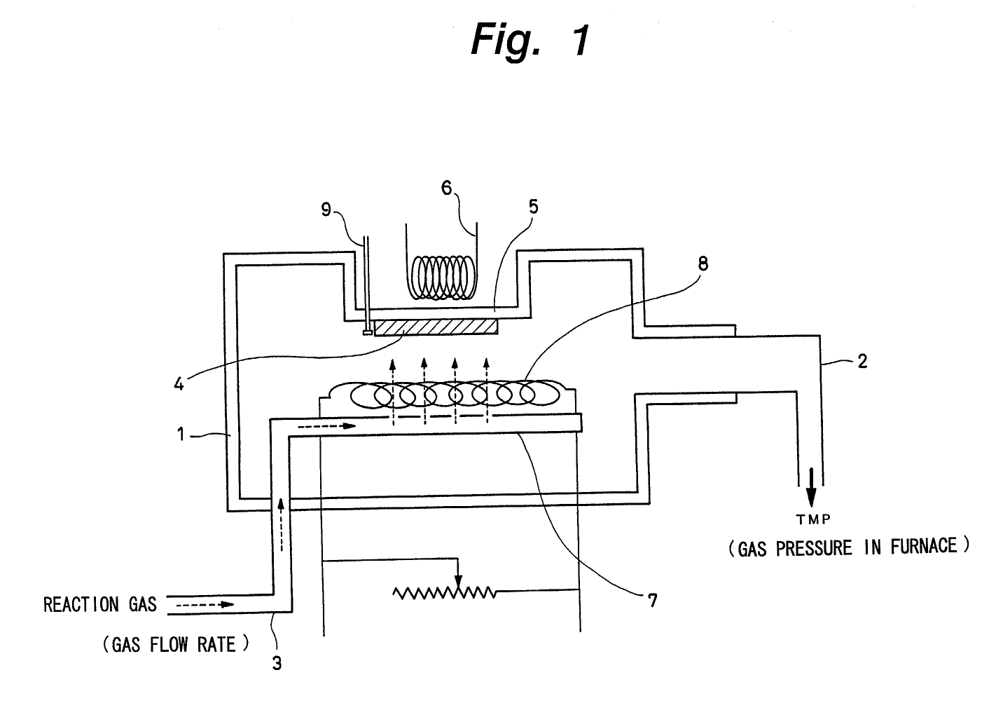

First explained is a catalytic CVD apparatus used for growth of a polycrystalline silicon layer in the embodiment. FIG. 1 shows an example of catalytic CVD apparatus.

As shown in FIG. 1, the catalytic CVD apparatus includes a growth chamber 1 having a side wall to which a turbo molecular pump (TMP) is connected by an evacuation pipe 2. The growth chamber 1 can be evacuated by this TMP to a pressure around 1×10⁻⁶ Pa, for example. At the bottom portion of the growth chamber l, a gas supply pipe 3 is attached to supply reactant gas used for growth through the gas supply pipe 3 into the growth chamber 1. A substrate 4 for growing a polycrystalline silicon layer thereon is set to a sample holder portion 5 provided in an upper center inside the growth chamber 1 via a load lock chamber, not shown. The sample holder portion 5 may be a graphite susceptor coated with SiC, for example, and can be heated by a heater 6 from the atmospheric air side. The sample holder portion 5 may be a graphite susceptor coated with SiC, for example, and can be heated by a heater 6 from the atmospheric air side.

Temperature of the substrate 4 can be measured by a thermocouple 9 attached to the substrate holder 5 at one side of the substrate 4.

Next explained is a growth method of a polycrystalline silicon layer by catalytic CVD according to this embodiment.

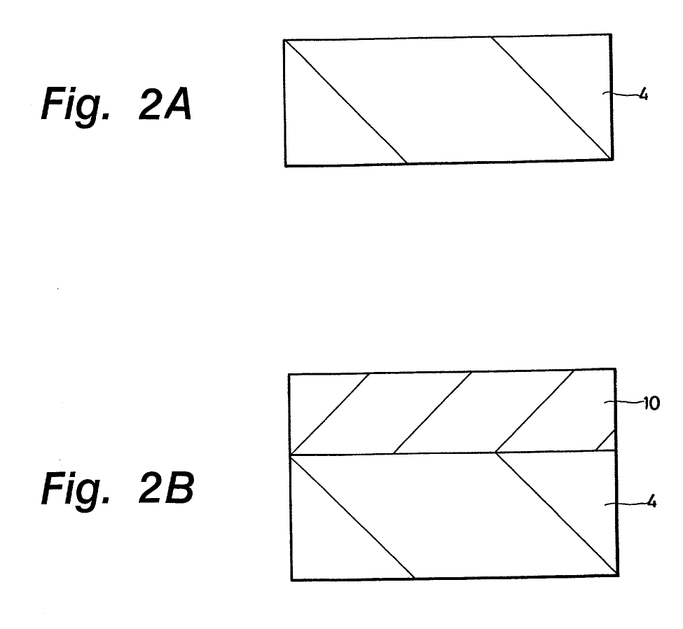

In this embodiment, as shown in FIG. 2A, first prepared is a substrate 4 which is then washed and dried. Usable as the substrate 4 are a glass substrate, quartz substrate, silicon substrate having formed an oxide silicon (SiO₂) film on its surface, and so on.

After that, the substrate 4 is mounted to the susceptor of the sample holder portion 5 inside the growth chamber 1 of the catalytic CVD apparatus shown in FIG. 1 through a load lock chamber, not shown. The susceptor of the sample holder portion 5 is previously adjusted to the growth temperature by the heater 6.

After that, the interior of the growth chamber 1 is reduced in pressure to about (1˜2)×10^{31 6} Pa, for example, by TMP, especially to discharge oxygen and moisture brought into the growth chamber 1 from outside. Time required for the discharge is approximately 5 minutes, for example.

Subsequently, hydrogen is supplied from the gas supply pipe 3 into the growth chamber 1, while controlling its flow rate, pressure and the susceptor temperature to predetermined values. Pressure in the growth chamber 1 was changed in the range of 0.1˜13.3 Pa (0.8˜100 mTorr). the hydrogen flow rate is adjusted to 30 sccm/min.

After that, the catalyst 8 is electrically conducted to heat it 1800° C. and it is maintained at this temperature for 10 minutes, for example. The reason why hydrogen is kept flowing into the growth chamber 1 as mentioned above lies in preventing oxidation of the catalyst 8 during heating.

After that, silane is supplied in addition to hydrogen from the gas supply pipe 3 into the growth chamber 1 to grow a silicon layer of a predetermined thickness, namely, about 0.5 μm, for example. Flow amount of hydrogen is adjusted to 30 sccm/min, for example, and flow amount of silane is adjusted to 0.3˜2 sccm/min (100% silane is used). In this manner, a polycrystalline silicon layer 10 is grown on the substrate 4 as shown in FIG. 2B.

After the growth, silane flow amount to the growth chamber 1 is set to zero, and about 5 minutes later, for example, the power supply to the catalyst 8 is interrupted to decrease its temperature.

Thereafter, hydrogen flow amount to the growth chamber 1 is set to zero, and the pressure is reduced to about (1˜2)×10⁻⁶ Pa. Particularly, silane introduced into the growth chamber is discharged. It takes about 5 minutes for this discharge.

After that, the substrate 4 having the polycrystalline silicon layer 10 grown thereon is taken out from the growth chamber 1 via a loadlock chamber, not shown.

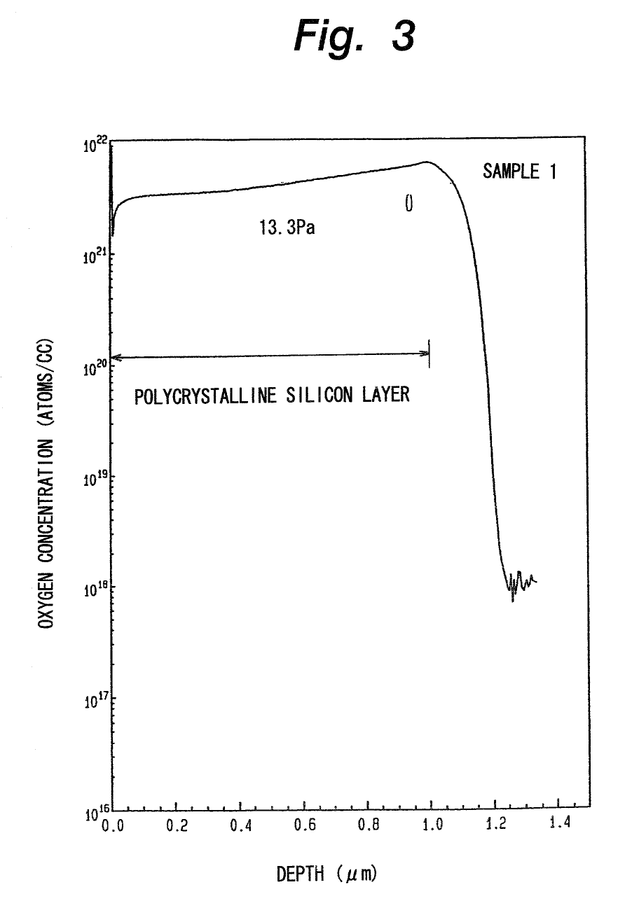

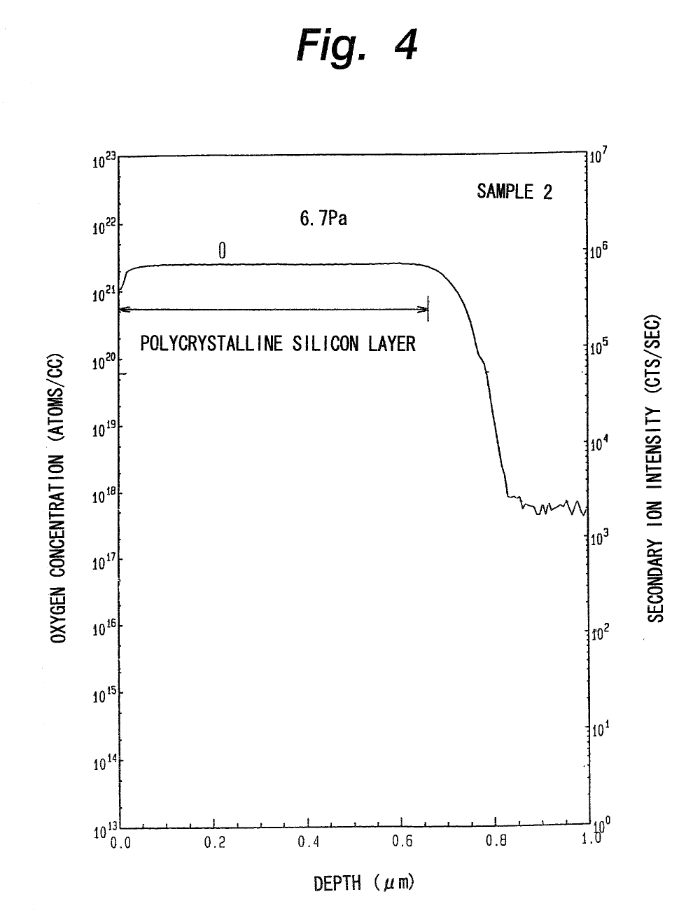

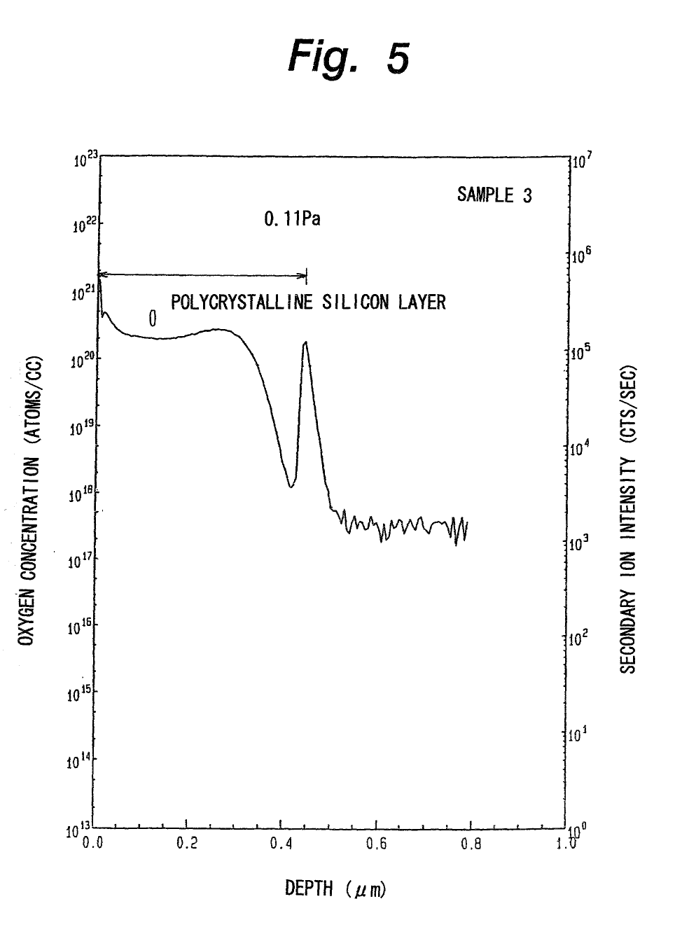

Polycrystalline silicon layers actually grown in the above-explained process were evaluated by using SIMS and a sectional transmission electron microscope (TEM). FIGS. 3 through 6 show results of SIMS measurement. Results of evaluation of the maximum oxygen concentration near the boundary between the polycrystalline silicon layer and the substrate of these samples are collectively shown in Table 1 together with their growth conditions. Samples 1 through 4 use silicon substrates as their substrates 4. In Table 1, T_{cat} is the temperature of the catalyst 8, and Tₛᵤₛ is the temperature of the susceptor of the substrate holder portion 5.

TABLE 1

| | Growth | Oxygen | |
|---|---|---|---|
| Sample | Pressure | Concentration | Growth |
| No. | (Pa) | (atoms/cc) | Condition |
| 1 | 13.3 | about 7 × 10²¹ | SiH₄ 3 sccm T_{cat} = 1700° C. |
| | | | H₂ 90 sccm Tₛᵤₛ = 260° C. |
| 2 | 6.7 | about 2 × 10²¹ | SiH₄ 1.5 sccm T_{cat} = 1700° C. |
| | | | H₂ 100 sccm Tₛᵤₛ = 360° C. |
| 3 | 0.11 | about 1 × 10¹⁸ | SiH₄ 0.25 sccm T_{cat} 1700° C. |
| | | | H₂ 30 sccm Tₛᵤₛ = 400° C. |

It is apparent from Table 1 that the maximum oxygen concentration in the polycrystalline silicon layer grown by catalytic CVD (especially that near the boundary with the substrate 4) is getting higher as the growth pressure increases, and oxygen brought into the growth layer increases in proportion to the growth pressure. Especially in the samples 1 and 2 under the growth pressure in the range from 13.3 Pa (100 mTorr) to 6.7 Pa (50 mTorr), oxygen of (7˜2)×10²¹ atoms/cc (14˜4 at %) is contained. In the sample 3 under the growth pressure of 0.11 Pa (0.8 mTorr), oxygen of 1×10¹⁸ atoms/cc (2×10⁻³ at %) is contained. It is also apparent that oxygen concentration increases with growth time.

Subsequently, after cleaning the inner wall of the growth chamber 1, polycrystalline silicon layers were grown by catalytic CVD in the same manner as explained above.

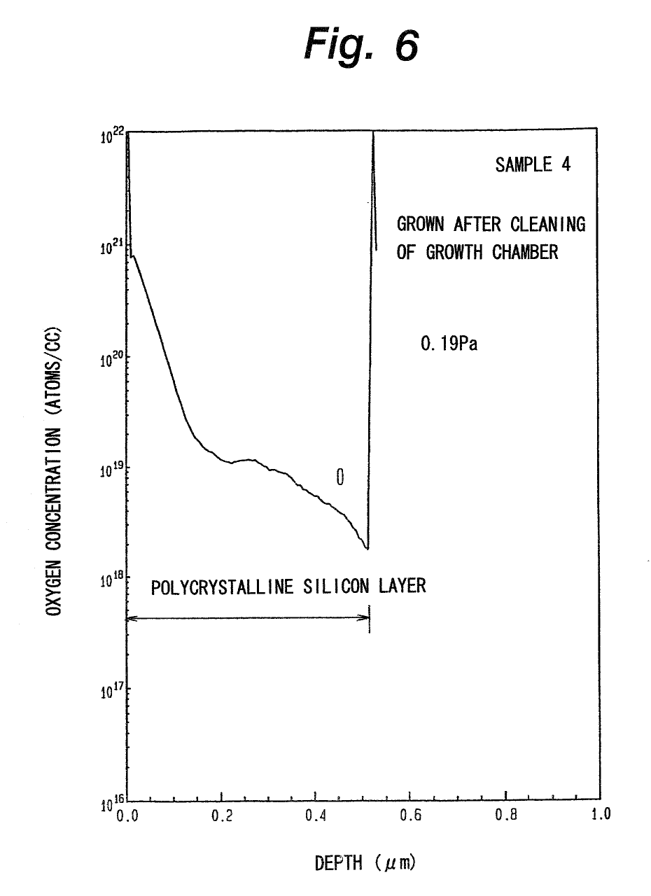

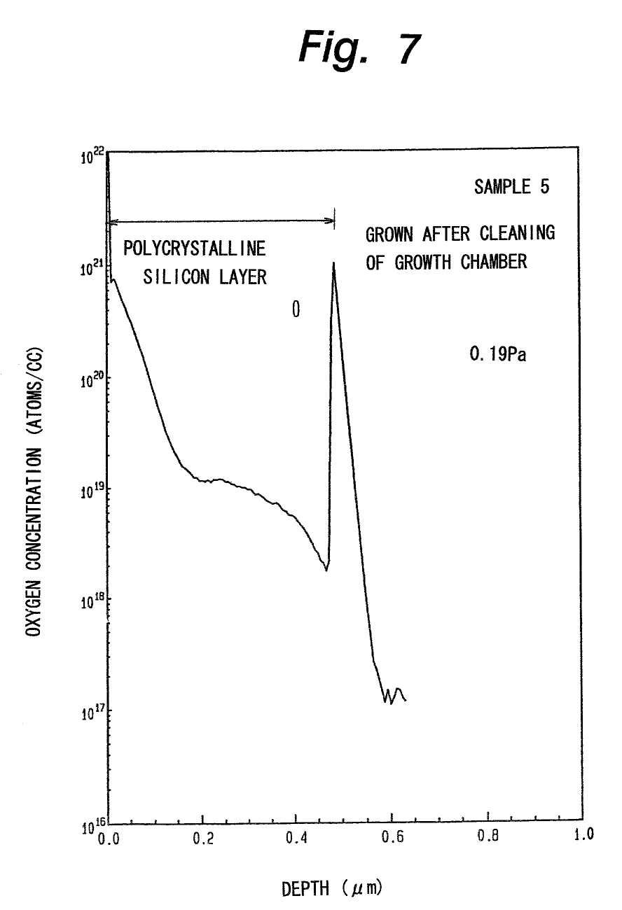

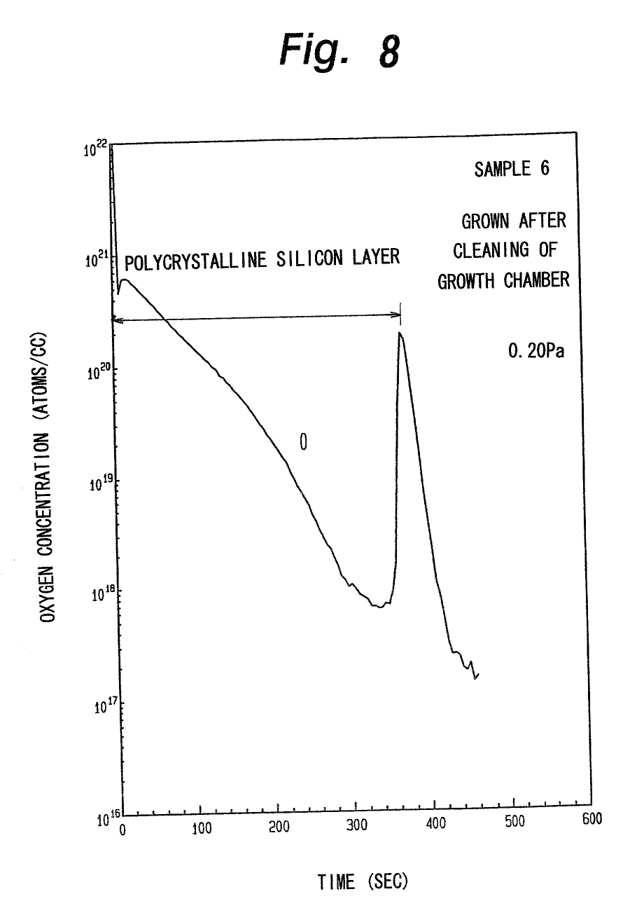

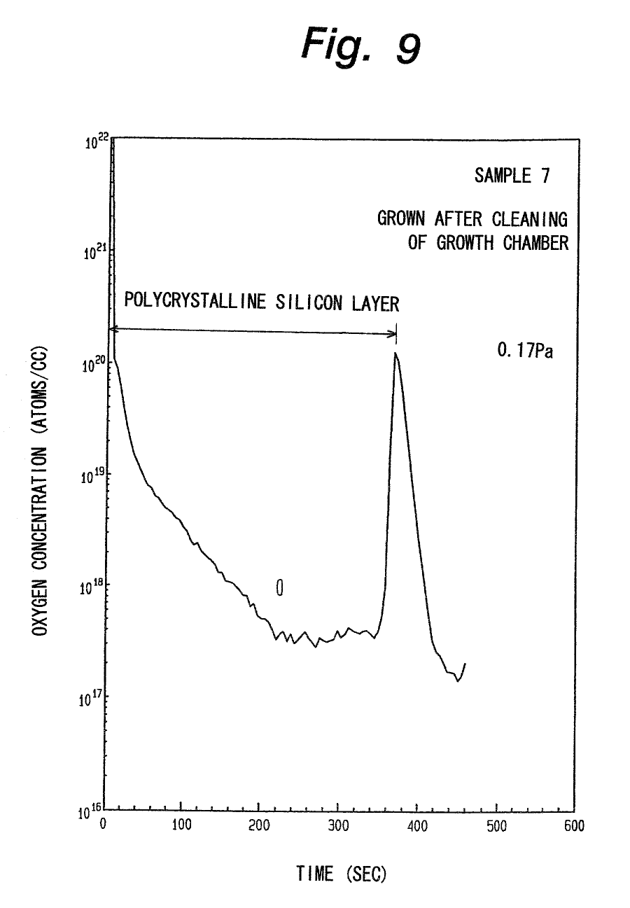

This cleaning is conducted by mechanical cleaning. FIGS. 6 through 9 show results of SIMS measurement. Results of evaluation of the maximum oxygen concentration in the polycrystalline silicon layers of these samples are collectively shown in Table 1 together with their growth conditions. The sample 4 uses a quartz substrate as its substrate 4, and samples 5, 6 and 7 use silicon substrate as their substrates 4.

TABLE 2

| | Growth | Oxygen | |
|---|---|---|---|
| Sample | Pressure | Concentration | Other Growth |
| No. | (Pa) | (atoms/cc) | Condition |
| 4 | 0.19 | about 2 × 10¹⁸ | SiH_{4 1.5 sccm T}_{cat} = 1800° C. |
| | | | H₂ 30 sccm Tₛᵤₛ 370° C. |
| 5 | 0.19 | about 2 × 10¹⁸ | SiH₄ 1.5 sccm T_{cat} = 1800° C. |
| | | | H₂ 30 sccm Tₛᵤₛ = 370° C. |
| 6 | 0.20 | about 7 × 10¹⁷ | SiH₄ 1.0 Sccm T_{cat} = 1800° C. |
| | | | H₂ 30 sccm Tₛᵤₛ = 370° C. |
| 7 | 0.17 | about 3.5 × 10¹⁷ | SiH₄ 0.3 sccm T_{cat} = 1800° C. |
| | | | H₂ 30 sccm Tₛᵤₛ = 370° C. |

It is apparent from Table 2 that the maximum oxygen concentration in polycrystalline silicon layers grown under the growth pressure around 0.19 Pa (1.4 mTorr) can be controlled within the range of 10¹⁸˜10¹⁷ atoms/cc with a good reproducibility. The reason why the oxygen concentration can be controlled low probably lies in the growth pressure being controlled as low as approximately 0.19 Pa and the cleaning of the inner wall of the growth chamber 1, which results in a decrease of the released amount of oxygen caused by the extraneous matters on the inner wall. Further, it is also apparent that an increase the silane/hydrogen flow ratio contributes to a decrease of the oxygen concentration in polycrystalline silicon layers. Furthermore, as apparent from comparison between the sample 4 using a quartz substrate as the substrate 4 and the sample 5 using a silicon substrate as the substrate 4, there is no difference in maximum oxygen concentration in polycrystalline silicon layers grown thereon, between the quarts substrate and the silicon substrate used as the substrates 4.

Next explained are results of sectional TEM observation. First prepared were samples 8, 9 and 10. The sample 8 was prepared by growing a polycrystalline silicon layer to the thickness of 485 nm on a silicon substrate having formed an oxide silicon (SiO₂) film on its surface, by catalytic CVD under the conditions of the growth pressure being 14 Pa (105 mTorr), silane flow rate being 9 sccm, hydrogen flow rate being 90 sccm, T_{cat}=1700° C. and Tₛᵤₛ=370° C. The sample 9 was prepared by growing a polycrystalline silicon layer to the thickness of 400 nm on a quartz substrate by catalytic CVD under the conditions of the growth pressure being 0.19 Pa (1.4 mTorr), silane flow rate being 0.75 sccm, hydrogen flow rate being 30 sccm, T_{cat}=1800° C. and Tₛᵤₛ=370° C. The sample 10 was prepared by growing a polycrystalline silicon layer to the thickness of 480 nm on a silicon substrate having formed an oxide silicon film on its surface, by catalytic CVD under the conditions of the growth pressure being 0.19 Pa (1.4 mTorr), silane flow rate being 0.75 sccm, hydrogen flow rate being 30 sccm, T_{cat}=1800° C. and Tₛᵤₛ=370° C. For preparation of the sample 9, a platinum (Pt) film was formed on the outermost surface of the polycrystalline silicon layer for the purpose of protecting the surface of the sample during fabrication.

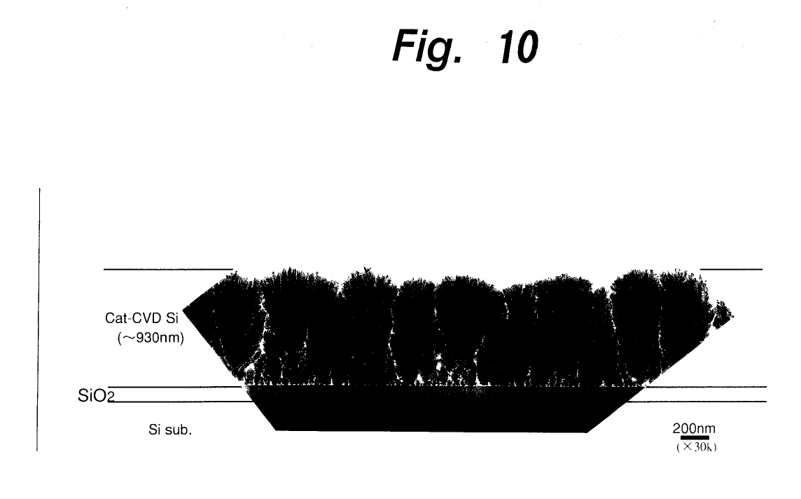

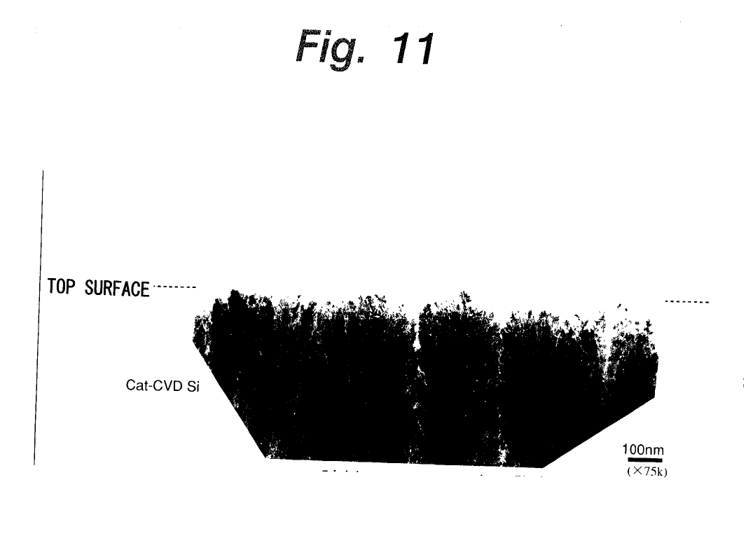

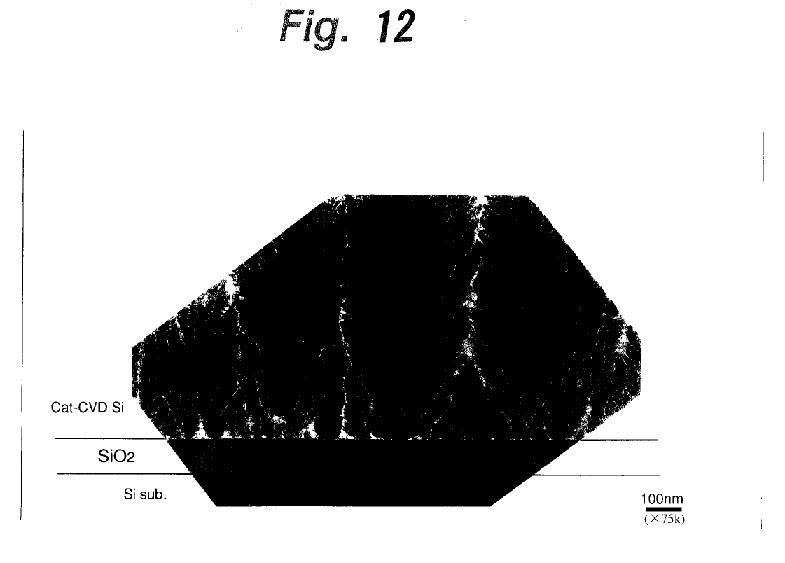

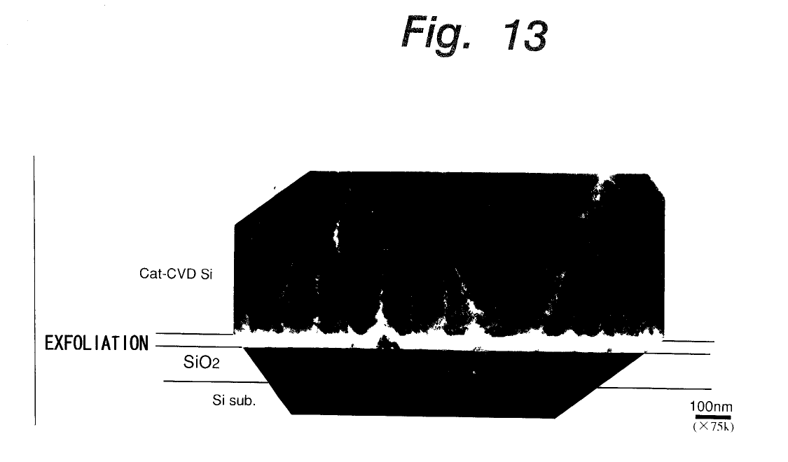

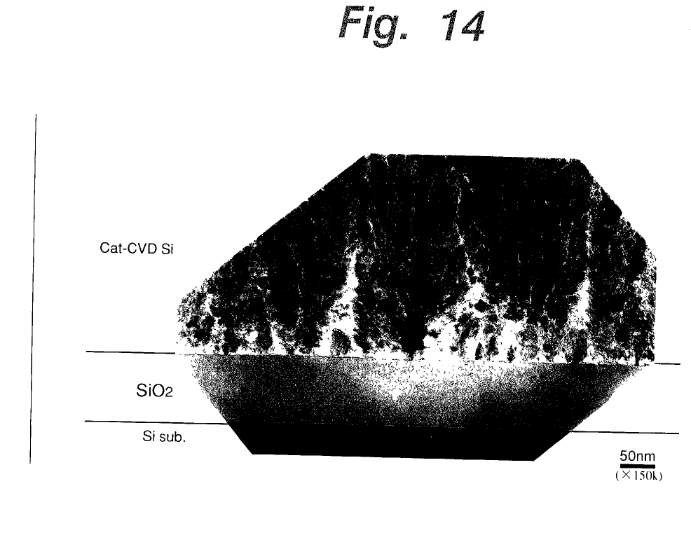

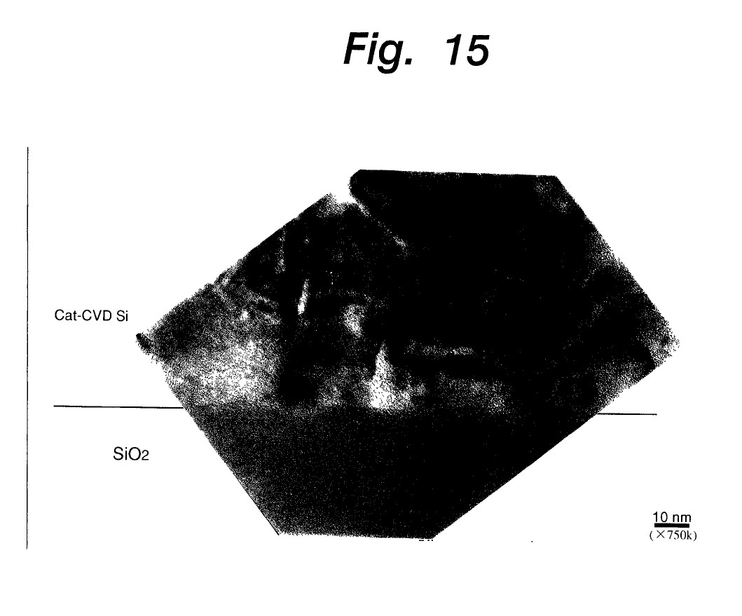

FIGS. 10 through 15 are sectional TEM photographs of the sample 8. FIG. 10 is a sectional TEM photograph of the entire aspect of a cross section of the polycrystalline silicon layer, taken by a low magnification. FIG. 11 is a sectional TEM photograph of the outermost surface portion of the polycrystalline silicon layer. FIG. 12 is a sectional TEM photograph of a boundary portion between the polycrystalline silicon layer and the oxide silicon film. FIG. 13 is a sectional TEM photograph of a boundary portion between the polycrystalline silicon layer and the oxide silicon film in a region where exfoliation of the polycrystalline silicon layer occurred. FIGS. 14 and 15 are sectional TEM photographs of a boundary portion between the polycrystalline silicon layer and the oxide silicon film taken by a high magnification. It is apparent from FIGS. through 15 that the maximum unevenness height along the surface of the polycrystalline silicon layer was about 100 nm, exfoliation locally occurred along the oxide silicon film/silicon substrate boundary (FIG. 13), and the grain size was 5˜10 nm.

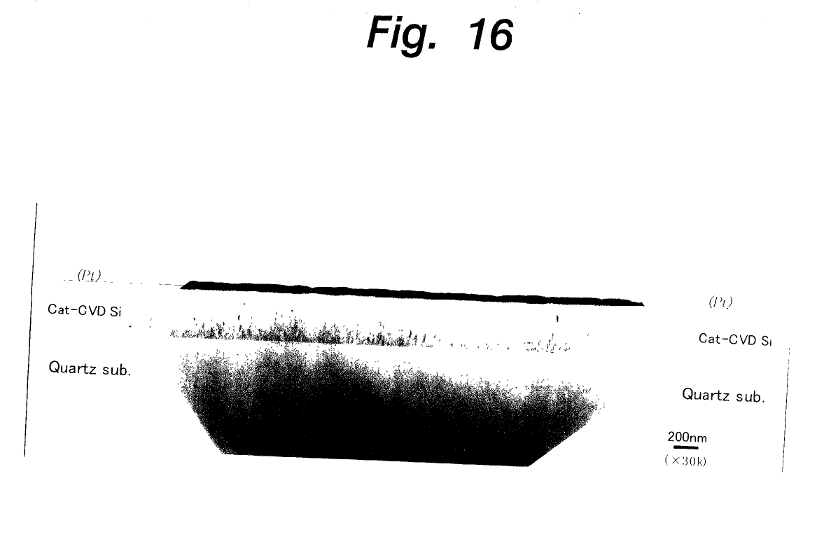

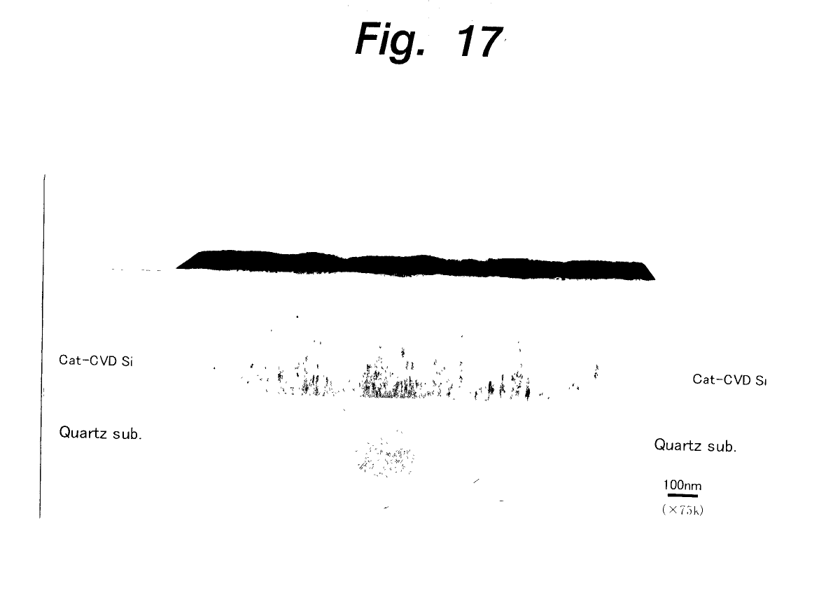

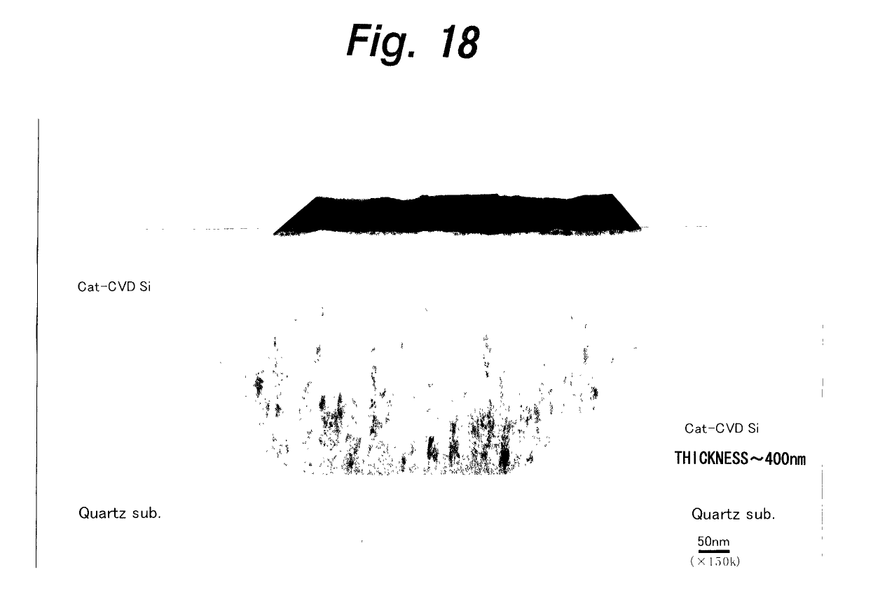

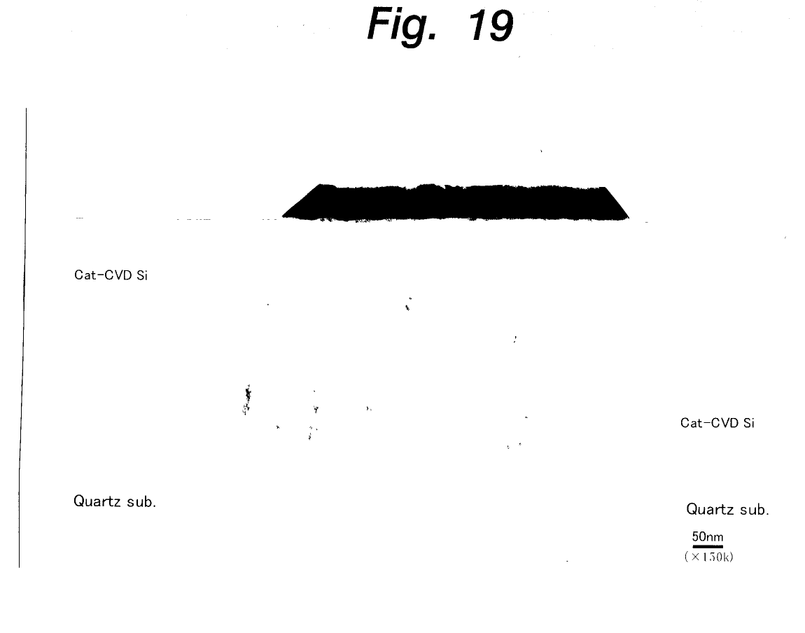

FIGS. 16 through 19 are sectional TEM photographs of the sample 9. FIG. 17 is a sectional TEM photograph of the entire aspect of a cross section of the polycrystalline silicon layer, taken by a low magnification. FIG. 18 is a sectional TEM photograph of a boundary portion between the polycrystalline silicon layer and the quartz substrate film. FIG. 19 is a sectional TEM photograph of a boundary portion between the polycrystalline silicon layer and the quartz substrate, different from the portion of FIG. 18, taken by a high magnification. It is apparent from FIGS. 16 through 19 that the maximum unevenness height along the surface of the polycrystalline silicon layer was about 5˜10 nm, and exfoliation did not occur along the boundary between the polycrystalline silicon layer and the quartz substrate. Additionally, the polycrystalline silicon layer was a crystal mad up of thin, elongated, column-shaped (needle-like) crystal grains, and the crystal grain size was very small, having the thickness (width) of the column-shaped crystal grain of about 5˜20 nm and the length (height) of 5˜100 nm.

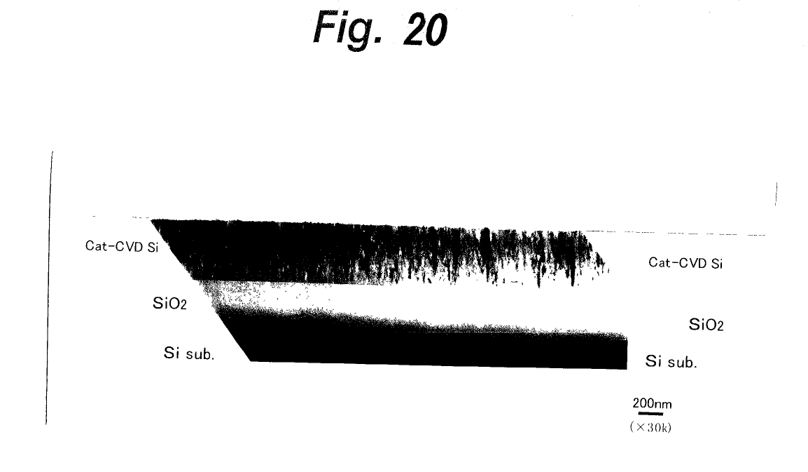

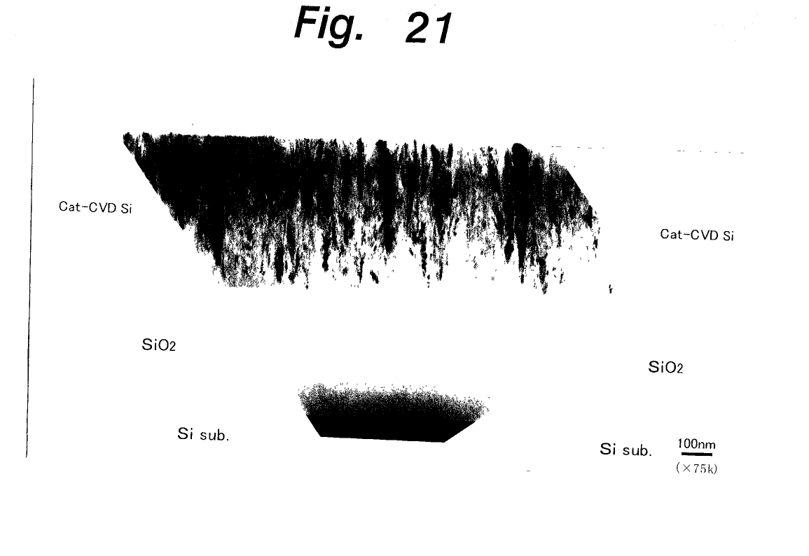

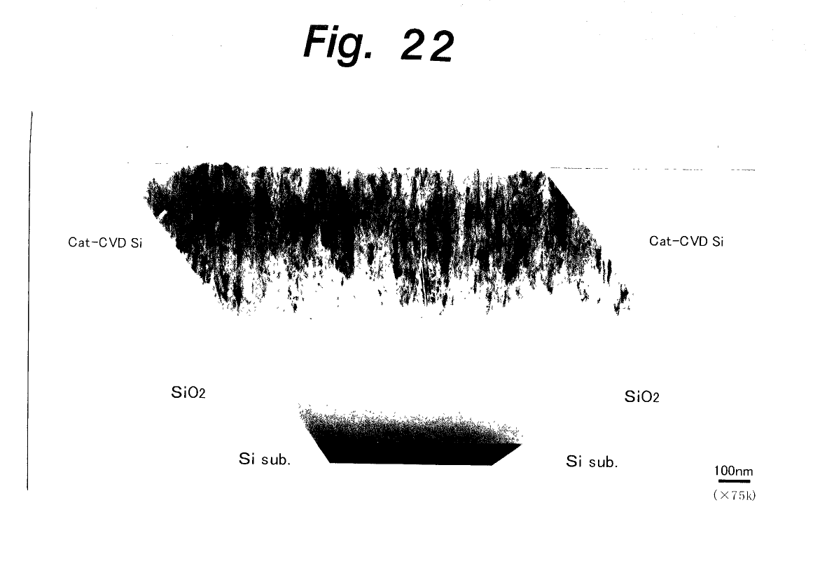

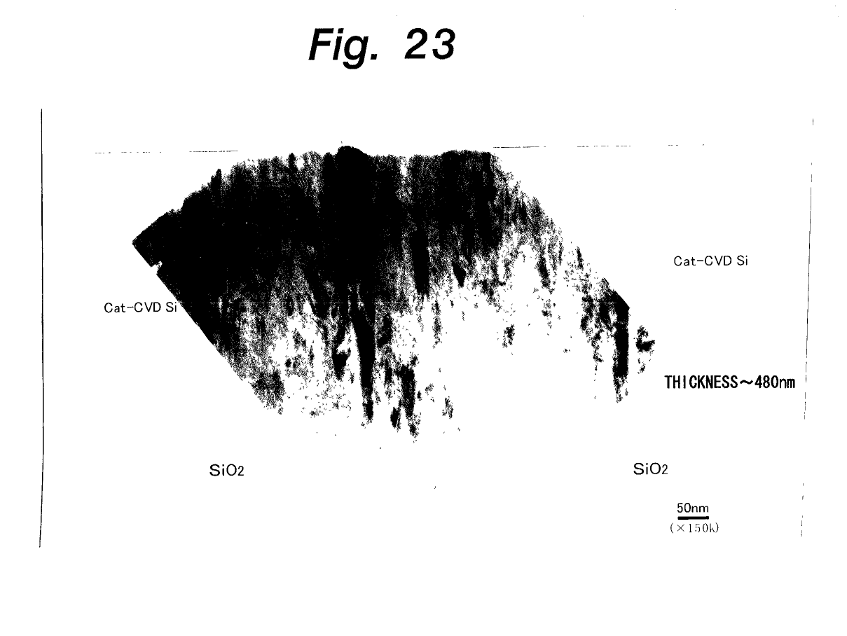

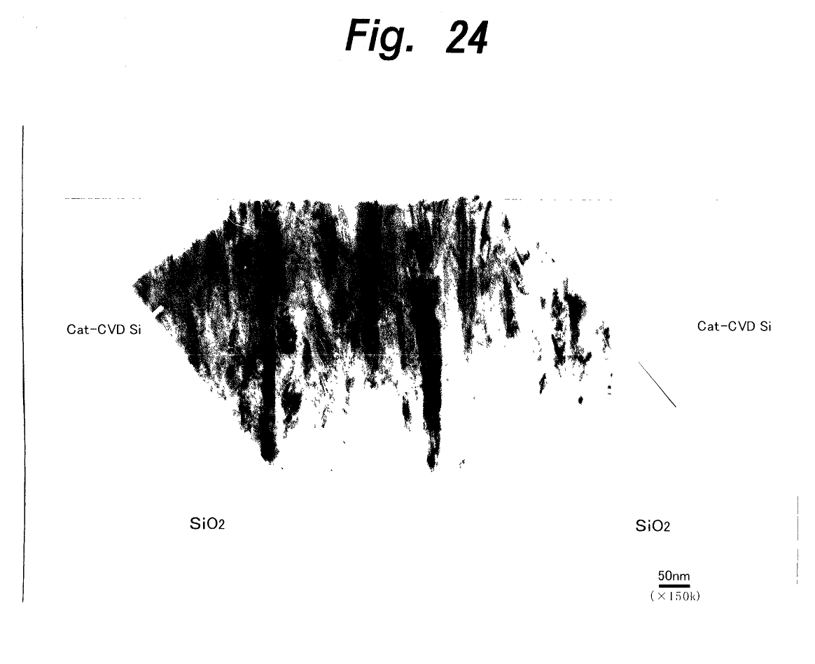

FIGS. 20 through 24 show sectional TEM photographs of the sample 10. FIG. 20 is a sectional TEM photograph of the entire aspect of a cross section of the polycrystalline silicon layer taken by a low magnification. FIG. 21 is a sectional TEM photograph of a boundary portion between the polycrystalline silicon layer and the oxide silicon film taken by a high magnification. FIG. 22 is a sectional TEM photograph of another boundary portion between the polycrystalline silicon layer and the oxide silicon film, different from that of FIG. 21, taken by the same magnification. FIG. 23 is a sectional TEM photograph of a boundary portion between the polycrystalline silicon layer and the oxide silicon film taken by a still higher magnification. FIG. 24 is a sectional TEM photograph of another boundary portion between the polycrystalline silicon layer and the oxide silicon film, different from that of FIG. 23, taken by the same magnification. It is apparent from FIGS. 20 through 24 that the maximum unevenness height along the surface of the polycrystalline silicon layer was about 5˜10 nm, and exfoliation did not occur along the boundary between the polycrystalline silicon layer and the SiO₂ film. Additionally, the polycrystalline silicon layer was a crystal mad up of thin, elongated, column-shaped (needle-like) crystal grains, and the crystal grain size was very small, having the thickness (width) of the column-shaped crystal grain of about 10˜50 nm and the length (height) of decades of nm through 100 nm.

As shown and explained above, by using catalytic CVD setting the growth pressure for growth of a polycrystalline silicon layer sufficiently low, namely, around 0.13 Pa (1 mTorr), for example, it is possible to grow a polycrystalline silicon layer having the maximum oxygen concentration not hither than 5×10¹⁸ atoms/cc at least in its region with the thickness of 10 nm, or 50 nm or even 100 nm, from the boundary with the substrate 4. This polycrystalline silicon layer has a high quality excellent in surface morphology, crystal grain size, oxygen concentration, exfoliation property, and crystallization ratio, required for use in TFT. More specifically, it is possible to grow a polycrystalline silicon layer having a flat or smooth surface, grain size not smaller than 5 nm, oxygen concentration not higher than 0.001 at %, not exfoliation from the base, and having a crystallization ratio not lower than 85%. In addition to that, since catalytic CVD used for growth of the polycrystalline silicon layer contributes to ensuring a reaction efficiency of reactant gas like silane as high as decades %, the method can save the resources and decreases the load to the environment, and also contributes to a reduction of the growth cost.

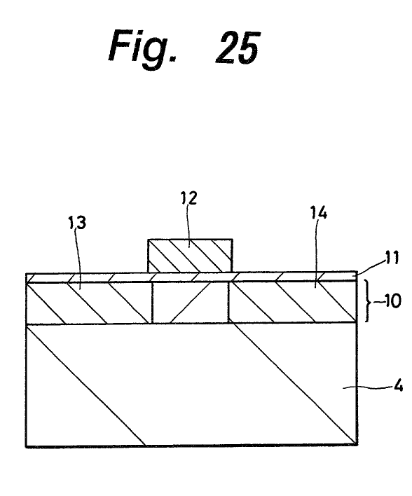

FIG. 25 shows an example of TFT using a polycrystalline silicon layer grown by the method according to the foregoing embodiment. That is, as shown in FIG. 25, this TFT includes a polycrystalline silicon layer 10 grown by catalytic CVD according to the foregoing embodiment on a substrate 4 such as glass substrate or quartz substrate. Thickness of the polycrystalline silicon layer 10 is around 10 through 100 nm, and its maximum oxygen concentration is not higher than 5×10¹⁸ atoms/cc. Grown on the polycrystalline silicon layer 10 is a gate insulating film 11 such as Sio₂ film by plasma CVD, for example. Formed on the gate insulating film 11 is a gate electrode 12 made of a polycrystalline silicon layer doped with an impurity, for example. In the single crystal silicon layer 10, a source region 13 and a drain region are formed in self alignment with the gate electrode 12. The polycrystalline silicon layer 10 in the region between these source region 13 and drain region 14 form a carrier channel.

Since the polycrystalline silicon layer 10 forming the carrier channel has high quality excellent in surface morphology, crystal grain size, oxygen concentration, exfoliation property, and crystallization ratio, a high-performance TFT having a high carrier mobility and a high reliability can be obtained.

Having described a specific preferred embodiment of the present invention with reference to the accompanying drawings, it is to be understood that the invention is not limited to that precise embodiment, and that various changes and modifications may be effected therein by one skilled in the art without departing from the scope or the spirit of the invention as defined in the appended claims.

More specifically, processes, numerical values and substrate materials, for example, are mere proposed examples, and any other appropriate processes, numerical 104 values, substrate materials, and so on, may be used. Additionally, the catalytic CVD apparatus used in the foregoing embodiment is also a mere example, and other catalytic CVD apparatuses different from that in structure are also usable, if necessary. The catalyst may also be other than W.

As described above, according to the invention, in case of growing a polycrystalline silicon layer on a substrate by catalytic CVD, since the polycrystalline silicon layer is grown by maintaining the total pressure of the growth atmosphere in the range from 1.33×10⁻³ Pa to 4 Pa at least in an initial portion of the growth period, or it is grown at least in the initial period of growth by maintaining the partial pressure of oxygen and moisture in the growth atmosphere in the range from 6.65×10⁻¹⁰ to 2×10⁻⁶ Pa, it is possible to grow the polycrystalline silicon layer having an oxygen concentration not higher than 5×10¹⁸ atoms/cm³ at least in a region with the thickness of 10 nm from the boundary between the substrate and the polycrystalline silicon layer. This polycrystalline silicon layer has a high quality required for use as a polycrystalline silicon layer of TFT. Additionally, by using this polycrystalline silicon layer, a high-performance semiconductor device such as TFT can be realized as well.

What is claimed is:

1. A polycrystalline silicon layer grown on a substrate by catalytic CVD, characterized in:
the maximum oxygen concentration thereof being not higher than 5×10¹⁸ atoms/cm³ at least in a region having the thickness of 10 nm from the boundary between said substrate and said single crystal silicon layer.

2. The polycrystalline silicon layer according to claim 1 wherein the maximum oxygen concentration thereof is not higher than 2.5×10¹⁸ atoms/cm³ at least in a region having the thickness of 10 nm from the boundary between said substrate and said polycrystalline silicon layer.

3. The polycrystalline silicon layer according to claim 1 wherein the maximum oxygen concentration thereof is not higher than 5×10¹⁸ atoms/cm³ at least in a region having the thickness of 50 nm from the boundary between said substrate and said polycrystalline silicon layer.

4. The polycrystalline silicon layer according to claim 1 wherein the maximum oxygen concentration thereof is not higher than 5×10¹⁸ atoms/cm³ at least in a region having the thickness of 100 nm from the boundary between said substrate and said polycrystalline silicon layer.

5. A polycrystalline silicon layer having a thickness not exceeding 100 nm grown by catalytic CVD on a substrate, characterized in:
the maximum oxygen concentration thereof being 5×10¹⁸ atoms/cm³.

6. The polycrystalline silicon layer according to claim 5 wherein thickness of said polycrystalline silicon layer does not exceed 50 nm.

7. The polycrystalline silicon layer according to claim 5 wherein the maximum oxygen concentration is not higher than 2.5×10¹⁸ atoms/cm³.

8. A polycrystalline silicon layer grown on a substrate by catalytic CVD, characterized in:
being grown by maintaining the total pressure of the growth atmosphere in the range from 1.33×10⁻³ Pa to 4 Pa at least in an initial period of the growth.

9. A polycrystalline silicon layer grown on a substrate by catalytic CVD, characterized in:
being grown by maintaining the partial pressure of oxygen and moisture in the growth atmosphere in the range from 6.65×10⁻¹⁰ Pa to 2×10⁻⁶ Pa at least in an initial period of the growth.

10. A growth method for growing a polycrystalline silicon layer by catalytic CVD on a substrate, characterized in:
the total pressure of the growth atmosphere being maintained in the range from 1.33×10⁻³ Pa to 4 Pa at least in an initial period of the growth.

11. A growth method for growing a polycrystalline silicon layer by catalytic CVD on a substrate, characterized in:
the partial pressure of oxygen and moisture in the growth atmosphere being maintained in the range from 6.65×10⁻¹⁰ Pa to 2×10⁻⁶ Pa at least in an initial period of the growth.

12. A semiconductor device having a polycrystalline silicon layer which is grown by catalytic CVD on a substrate, characterized in:
said single polycrystalline layer having the maximum oxygen concentration of 5×10¹⁸ atoms/cm³ at least in a region thereof to be used as a carrier channel.
